(19) United States
(12) Patent Application Publication
(10) Pub. No.: US 2022/0322589 A1
(43) Pub. Date: Oct. 6, 2022

(54) ELECTRONIC COMPONENT REEL SET, ELECTRONIC COMPONENT MODULE, AND ELECTRIC CIRCUIT

(71) Applicant: ROHM CO., LTD., Kyoto-shi, Kyoto (JP)

(72) Inventors: Manabu OYAMA, Kyoto-shi, Kyoto (JP); Yoichi TAMEGAI, Kyoto-shi, Kyoto (JP)

(21) Appl. No.: 17/596,799

(22) PCT Filed: Jun. 15, 2020
(86) PCT No.: PCT/JP2020/023457

§ 371 Date: Dec. 17, 2021

(30) Foreign Application Priority Data
Jun. 28, 2019 (JP) 2019-120846

(51) Int. Cl. H05K 13/04; H05K 13/00; B65D 73/02; B65D 85/68

(52) U.S. Cl. CPC H05K 13/0419; H05K 13/003; B65D 73/02; B65D 85/68; B65D 2585/86

(57) ABSTRACT

An electronic component reel set includes a first electronic component reel and a second electronic component reel. The first electronic component reel includes first electronic components each having a first characteristic value falling in a predetermined range above a reference characteristic value, a first electronic component package that stores the first electronic components linearly, a first reel body in which the first electronic component package is wound, and a first indicator portion indicating the first characteristic value. The second electronic component reel includes second electronic components each having a second characteristic value falling in a predetermined range below the reference characteristic value, a second electronic component package that stores the second electronic components linearly, a second reel body in which the second electronic component package is wound, and a second indicator portion indicating the second characteristic value.

### TECHNICAL FIELD

The present disclosure relates to an electronic component reel set, an electronic component module, and an electric circuit.

### BACKGROUND ART

Conventionally, electronic components such as resistors, coils and capacitors may be inspected after manufactured, and when they have passed the inspection, they are shipped to users from the factory. In the inspection, electronic components are selected as proper products if their electric characteristics fall in a predetermined allowable error range based on the electric characteristic value serving as a reference or “reference characteristic value” (in the case of resistors, a resistor may be selected if its resistance value is in a range less than 1% from the reference resistance value.), and the selected electronic components are to be shipped. In shipping, the electronic components are arranged into an electronic component reel configured to carry a number of electronic components. Such an electronic component reel includes an electronic component package that stores a plurality of electronic components arranged in a line, and a reel body for winding the electronic component package (see e.g., Patent Document 1). On the other hand, electronic components having failed to pass the inspection are not used (i.e., discarded for instance), which lowers the product manufacturing yield.

### PRIOR ART DOCUMENTS

### Patent Document

Patent Document 1: JP-A-2017-171393

### SUMMARY OF THE INVENTION

### Problem to be Solved by the Invention

In light of the foregoing, the present disclosure is directed at improving the yield of electronic component manufacturing by making effective use of electronic components whose characteristic values fail to be in an allowable error range.

### Means for Solving the Problem

An electronic component reel set provided by an aspect of the present disclosure includes a first electronic component reel and a second electronic component reel. The first electronic component reel includes a plurality of first electronic components each having a first characteristic value falling in a predetermined range above a reference characteristic value, a first electronic component package that stores the plurality of first electronic components linearly, a first reel body for winding the first electronic component package, and a first indicator portion indicating the first characteristic value. The second electronic component reel includes a plurality of second electronic components each having a second characteristic value falling in a predetermined range below the reference characteristic value, a second electronic component package that stores the plurality of second electronic components linearly, a second reel body for winding the second electronic component package, and a second indicator portion indicating the second characteristic value.

Other features and advantages of the present disclosure will be apparent from the following detailed description with reference to the attached drawings.

### BRIEF DESCRIPTION OF DRAWINGS

FIG. 1 is a perspective view illustrating an electronic component reel according to a first embodiment.

FIG. 2 is a perspective view illustrating a part of an electronic component package that constitutes the electronic component reel.

FIG. 3 is a plan view of a part of the electronic component package shown in FIG. 2.

FIG. 4 is a cross-sectional view taken along line IV-IV in FIG. 3.

FIG. 5 is a perspective view illustrating an example of an electronic component.

FIG. 6 is a perspective view illustrating an electronic component module according to a second embodiment.

FIG. 7 is a plan view of the electronic component module shown in FIG. 6.

FIG. 8 is a cross-sectional view taken along line VIII-VIII in FIG. 7.

FIG. 9 is a cross-sectional view taken along line IX-IX in FIG. 7.

FIG. 10 is a cross-sectional view illustrating an electronic component module according to a third embodiment.

FIG. 11 is a block diagram illustrating a schematic configuration of an electric circuit according to a fourth embodiment.

FIG. 12 is a diagram illustrating an exemplary configuration of a current detection resistor.

FIG. 13 is a block diagram illustrating a schematic configuration of an electric circuit according to the fifth embodiment.

FIG. 14 is a diagram illustrating an exemplary configuration of first and second voltage-dividing resistors.

### MODE FOR CARRYING OUT THE INVENTION

Hereinafter, preferable embodiments of the present disclosure will be specifically described with reference to the drawings.

The terms such as “first” and “second” in the present disclosure are simply used as labels, and are not necessarily intended to give an order to objects to which such terms are added.

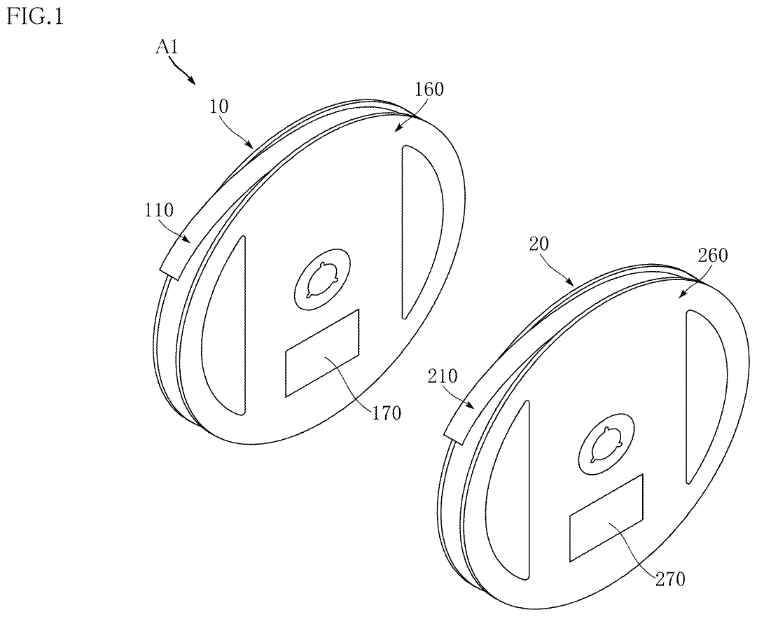

An electronic component reel set A1 according to a first embodiment will be described based on FIGS. 1 to 5. The illustrated electronic component reel set A1 includes a first electronic component reel 10 and a second electronic component reel 20. The first electronic component reel 10 includes a first electronic component package 110 and a first reel body 160. The second electronic component reel 20 includes a second electronic component package 210 and a second reel body 260.

The configurations of the first electronic component reel 10 and the second electronic component reel 20 are substantially the same other than the fact that first electronic components 150 differ from second electronic components 250. In the following, the first electronic component reel 10 will be mainly described with reference to the drawings, while the description of the second electronic component reel 20 will be appropriately omitted.

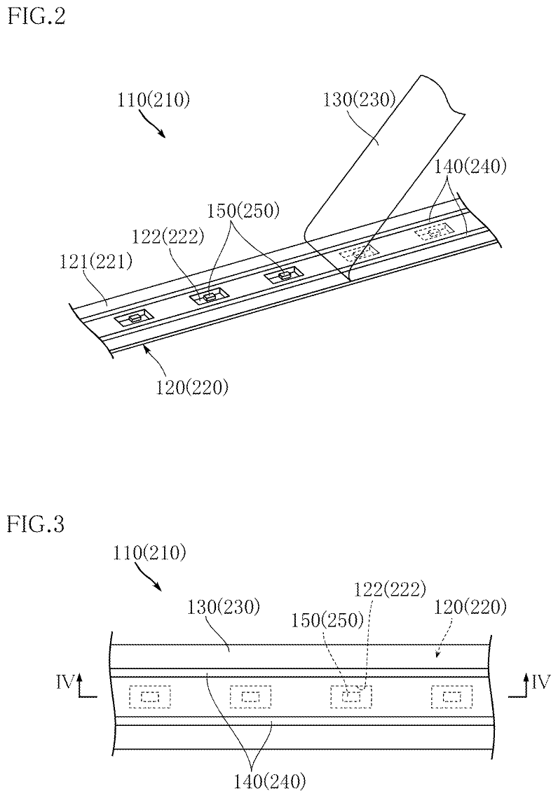

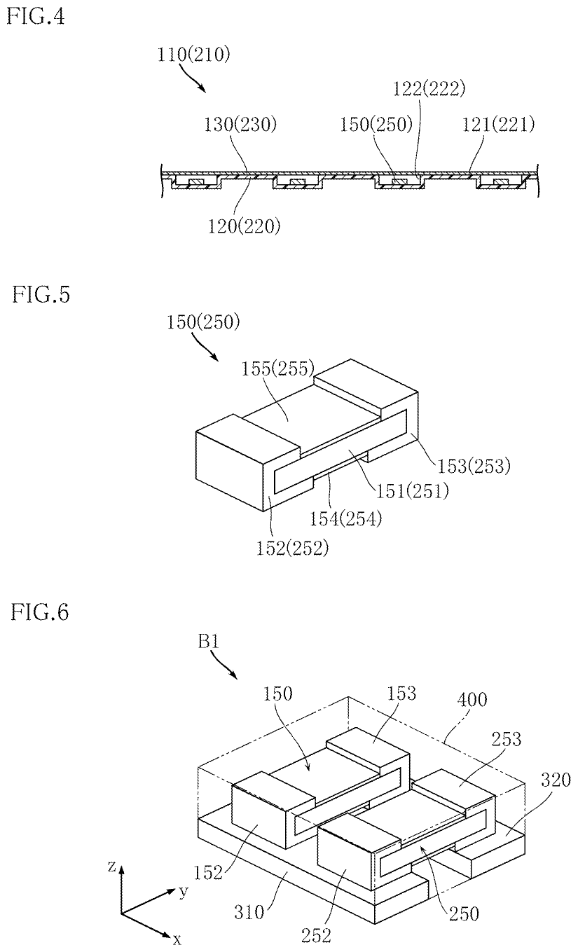

As shown in FIGS. 2 to 4, the first electronic component package 110 includes a carrier tape 120, a cover tape 130, a joining portion 140, and a plurality of first electronic components 150. FIG. 2 shows a state in which a portion of the cover tape 130 is peeled from the carrier tape 120. FIG. 3 is a plan view of a part of the first electronic component package 110 in a state in which the cover tape 130 is not peeled. FIG. 4 is a cross-sectional view taken along line IV-IV in FIG. 3.

The carrier tape 120 is made of an opaque polyethylene terephthalate (PET) resin or a polystyrene (PS) resin, and is shaped as a band that extends in a longitudinal direction. The illustrated carrier tape 120 is constituted by a resin sheet in which a plurality of storage recesses 122 are formed by embossing, for example. An example of the size of the carrier tape 120 is about 0.1 to 1.1 mm in thickness and about 4 to 12 mm in width. The material of the carrier tape 120 may be paper in place of resin, for example. Examples of the carrier tape 120 made of paper include a configuration in which a plurality of storage recesses 122 are formed by reducing the thickness of portions of a thick paper sheet whose thickness is relatively large. The plurality of storage recesses 122 are arranged along the longitudinal direction of the carrier tape 120 at equal intervals, and are provided to individually store the plurality of first electronic components 150. In the illustrated example, the plurality of storage recesses 122 are arranged at the center of the carrier tape 120 in the width direction. Each storage recess 122 is recessed from a principal face 121 of the carrier tape 120, and is in a rectangular shape in plan view, in the illustrated example. The shape of the storage recesses 122 in plan view may be various shapes suitable for the first electronic components 150 to be stored, such as a polygonal shape, a circular shape, and an elliptical shape, in addition to a rectangular shape.

The cover tape 130 is shaped as a band whose width is about the same as that of the carrier tape 120. The cover tape 130 has a configuration in which a base material layer and a joining layer are laminated, for example. The base material layer is made of a transparent or translucent polyethylene terephthalate (PET) resin. The joining layer is a layer that exhibits a joining function when subjected to heat and pressure, and is made of a polyethylene (PE) based resin, for example. The cover tape 130 covers the plurality of storage recesses 122 by being joined to the principal face 121 of the carrier tape 120. Accordingly, the first electronic components 150 are stored in the storage recesses 122 in a state of being completely closed to the outside. In order to allow the plurality of first electronic components 150 to be taken out, the cover tape 130 can be peeled from the carrier tape 120. When the carrier tape 120 is made of paper, the cover tape 130 is configured to be appropriately joined to and peeled off the paper.

The joining portion 140 is a portion at which the carrier tape 120 and the cover tape 130 are directly joined. In the illustrated example, the joining portion 140 is a portion formed by the joining function of the joining layer of the cover tape 130 being exhibited by thermocompression bonding, and includes two line-shaped portions. The two line-shaped portions are arranged apart from each other in the width direction of the carrier tape 120 on opposite sides of the plurality of storage recesses 122, and continuously extend in the longitudinal direction of the carrier tape 120.

The plurality of first electronic components 150 are relatively small electronic components such as chip resistors, chip inductors (coils), or capacitors, but the present disclosure is not limited thereto. In the illustrated example, the first electronic component 150 is a chip-shaped passive component having an elongated rectangular shape in plan view. The first electronic component 150 has a predetermined electric characteristic value. The plurality of first electronic components 150 are individually stored in the plurality of storage recesses 122, and are stored linearly (in a line) in the first electronic component package 110. In the following description, a case where the first electronic component 150 is a chip resistor will be described, but the present disclosure is not limited thereto.

As shown in FIG. 5, the chip resistor (first electronic component) 150 includes a base material 151, a pair of electrodes 152 and 153, and insulating films 154 and 155, for example. In the illustrated example, the chip resistor 150 is a thick film type of chip resistor, and the base material 151 is a resistor made of a predetermined metal material. The base material 151 has an elongated rectangular chip shape with a fixed thickness. The material of the base material 151 is not specifically limited, and a metal material having a resistivity that matches the target resistance value of the chip resistor 150 may be appropriately selected. Alternatively, a material suitable for giving the chip resistor 150 a desired size (e.g., a metal material) may be appropriately selected. Alternatively, the material of the base material 151 may also be selected with consideration given to a plurality of conditions (target resistance value, chip resistor size, and the like).

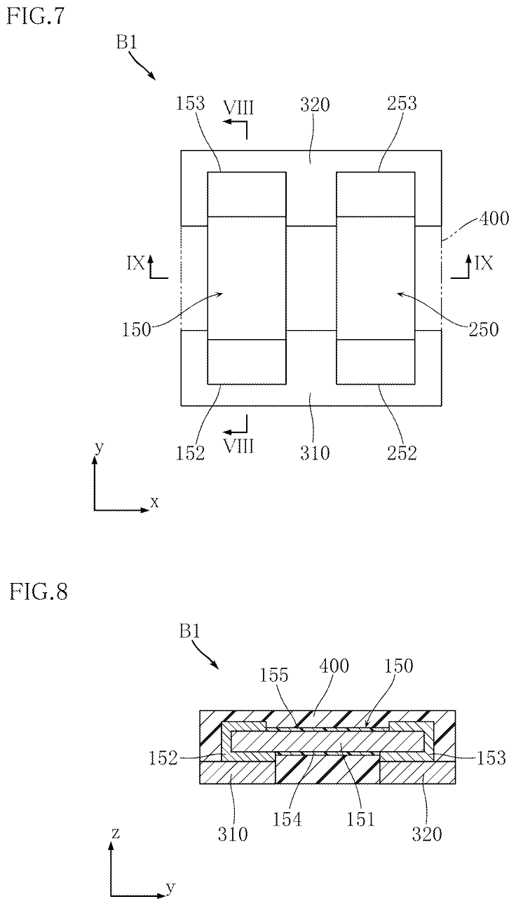

The electrodes 152 and 153 are provided apart from each other in the longitudinal direction of the base material 151. These electrodes 152 and 153 are made of a conductive material whose solder wettability is higher than that of the base material 151, and are made of a metal such as Cu, for example. For example, as shown in FIG. 5, the electrodes 152 and 153 each have a substantially U-shaped cross section and cover one end face of the base material 151 (one of two end faces of the base material 151 that are separated in the longitudinal direction), and an upper face and a lower face of the base material 151. In the illustrated example, the electrodes 152 and 153 cover the entirety of the respective end faces of the base material 151. Also, the electrodes 152 and 153 each cover some of the upper face and some of the lower face of the base material 151. As shown in FIG. 8, the electrodes 152 and 153 each include an upper side portion (portion that covers the upper face of the base material 151) and a lower side portion (portion that covers the lower face of the base material 151). In the illustrated example, the upper side portion of each electrode is shorter than the lower side portion (the size in a direction y is smaller), but the present disclosure is not limited thereto.

The insulating films 154 and 155 are coating films made of an epoxy resin-based resin, for example. The lower insulating film 154 is provided so as to cover a region of the lower face of the base material 151 between the electrodes 152 and 153. The upper insulating film 155 is provided so as to cover a region of the upper face of the base material 151 between the electrodes 152 and 153.

The size of the first electronic component 150 can be appropriately set. A non-limiting example of the size is as follows. The size in the longitudinal direction of the base material 151 is 0.4 to 7.0 mm, the size in the width direction is 0.2 to 3.5 mm, and the thickness is 0.1 to 2.0 mm.

The plurality of first electronic components 150 have respective first characteristic values each of which is larger than a particular electric characteristic value (“reference characteristic value”) relating to the electronic components (that is, first characteristic value>reference characteristic value). In the illustrated example, the first electronic component 150 has a first resistance value as the first characteristic value since it is a chip resistor. The first resistance value has a positive error relative to the reference characteristic value or reference resistance value (that is, first resistance value−reference resistance value=error>0). Further, in the present embodiment, the first resistance value is supposed to be in a predetermined range (“first error range” to be described). More specifically, when a chip resistor is produced and subjected to inspection, and if its resistance value is in a predetermined “allowable error range” (or “normal error range”), the chip resistor is labeled as a “normal product”. Here, the “allowable error range” refers to a section that is defined by an upper limit and a lower limit, and that contains the reference resistance value within the range. The upper limit value and lower limit value may or may not belong to this section, depending on the situation. In a certain case, the reference resistance value may be equal to the lower limit value (in this case, the lower limit value is included in, or belongs to, the section). With the upper limit value denoted as Vmax, the lower limit value as Vmin, and the reference resistance value as Rref, the relation between these values and the allowable error range can be represented as follows. Vmin<allowable error range<Vmax, where Rref ϵ allowable error range (“ϵ” means “belong to”). At least one of the two inequality signs (<) may be the sign of equality “≤”. When the lower limit value is the same as the reference resistance value, the relation can be represented as (Vmin=) Rref≤allowable error range<Vmax (this “<” may be ≤). In the illustrated example, on the other hand, the first electronic component 150 is an electronic component whose resistance value is out of the above-described allowable error range, deviating on the positive side (that is, the resistance value>Vmax or ≥Vmax). The error range of the resistance value of the first electronic component 150 (first resistance value), that is to say a “first error range”, is set above the “allowable error range” of the resistance value for the normal products. Similarly to the allowable error range, the first error range can be defined as a section between a lower limit value (V1 min) and an upper limit value (V1 max). The first resistance value of each relevant product is in this first error range. The allowable error range (index for normal products) and the first error range (index for first electronic components 150) are set appropriately according to the performance required for the electronic components. The lower limit value (V1 min) is a value at which the absolute value of the difference from the reference resistance value (Rref) (|V1 min−Rref| or |Rref−V1 min|) is smallest, and the upper limit value (V1 max) is a value at which the absolute value of the difference from the reference resistance value (|V1 max−Rref| or |Rref−V1 max|) is largest. The lower limit value and upper limit value of the first resistance value are determined based on an allowable ratio of the absolute value of the difference from the reference resistance value relative to the reference resistance value, for example. For example, when the allowable error range of the resistance value of normal products (specifically, upper limit value Vmax) is less than 1% of the reference resistance value, the first resistance value (resistance value of the electronic component 150) is in a range of 1 to 2% of the reference resistance value on the positive side (+1 to +2%). In other words, the lower limit of the resistance value of the first electronic component 150 is obtained by reference resistance value×1.01, and the upper limit is obtained by reference resistance value×1.02.

The first electronic component package 110 is transferred from a manufacturing factory to a user's factory in a state of being wound in the first reel body 160 and stored as needed. The first electronic component package 110 may also be configured to include a plurality of positioning holes (not illustrated) aligned in the longitudinal direction at a portion close to one end in the width direction so as to avoid the plurality of storage recesses 122. These positioning holes are used to feed the first electronic component package 110 by a predetermined length at a predetermine speed. The same applies to the later-described second electronic component package 210.

In the present embodiment, the first reel body 160 is provided with a first indicator portion 170. The first indicator portion 170 indicates the reference resistance value (reference characteristic value) and the first characteristic value (first resistance value) of the first electronic component 150. The way how the relevant information is given in the first indicator portion 170 is not specifically limited. For instance, “100 Ω+1˜2Ω” or “reference resistance value 100Ω, resistance value error range +1 to +2%” may be noted when the reference resistance value is 100Ω, and the error range of the resistance value (first resistance value) is 1 to 2% of the reference resistance value on the positive side. The first indicator portion 170 is constituted by an indication label attached to an appropriate position of the first reel body 160, for example. The configuration of the first indicator portion is not limited thereto, and may be realized by performing printing at an appropriate position of the first electronic component package 110 (e.g., cover tape 130), or the portion may be provided on both of the first reel body 160 and the first electronic component package 110.

The second electronic component package 210 is configured similarly to the first electronic component package 110 described above, and includes a carrier tape 220, a cover tape 230, a joining portion 240, and a plurality of second electronic components 250. In FIGS. 2 to 4, the elements corresponding to the carrier tape 220, the cover tape 230, the joining portion 240, and the second electronic component 250 are assigned reference numerals in parentheses, and detailed description thereof will be omitted.

The plurality of second electronic components 250 are relatively small electronic components such as chip resistors, chip inductors (coils), or capacitors. In the present embodiment, the second electronic component 250 has an elongated rectangular chip shape in plan view, and is a passive component. The second electronic component 250 has an electric characteristic value regarding the electronic component. The plurality of second electronic components 250 are individually stored in the plurality of storage recesses 222, and are linearly stored in the second electronic component package 210. In the following description, a case where the second electronic component 250 is a chip resistor will be described.

As shown in FIG. 5, the second electronic component 250, which is a chip resistor, is configured similarly to the first electronic component 150 described above, and includes a base material 251, a pair of electrodes 252 and 253, and insulating films 254 and 255, for example. In FIG. 5, the elements corresponding to the base material 251, the electrodes 252 and 253, and the insulating films 254 and 255 are assigned reference numerals in parentheses, and detailed description thereof will be omitted.

The plurality of second electronic components 250 each have second characteristic values that are smaller than an electric characteristic value (reference characteristic value), which is a reference relating to the electronic components. The second electronic component 250, which is a chip resistor, has a second resistance value as the second characteristic value. The second resistance value has a negative error relative to the reference resistance value as the reference characteristic value, and in the present embodiment, the difference from the reference resistance value is in a predetermined error range. The second electronic component 250 is an electronic component whose resistance value falls out of the allowable error range, deviating on a negative side. The allowable error range of the resistance value for normal products and the error range of the resistance value for the second electronic component 250, which is out of the allowable error range, are set appropriately according to the performance required for the electronic component. The resistance value (second resistance value) of the second electronic component 250 is in a range between an upper limit value and a lower limit value. The upper limit value is a value at which the absolute value of the difference from the reference resistance value is smallest, and the lower limit value is a value at which the absolute value of the difference from the reference resistance value is largest. The upper limit value and lower limit value of the second resistance value may be determined based on an allowable ratio of the absolute value of the difference from the reference resistance value relative to the reference resistance value. For example, when the allowable error range of the resistance value of a normal product is less than 1% of the reference resistance value, the second resistance value of the second electronic component 250 is in a range of 1 to 2% of the reference resistance value on the negative side (−1 to −2%). In this case, the upper limit value of the resistance value of the second electronic component 250 is obtained by reference resistance value×0.99, and the lower limit value of the resistance value is obtained by reference resistance value×0.98.

In the present embodiment, the range (second error range) of the second resistance value (second characteristic value) relative to the reference resistance value (reference characteristic value) can be said to be “equivalent” to the first error range (the range of the first resistance value relative to the reference resistance value). This means that the difference (absolute value) between the reference resistance value and the lower limit value of the resistance value of the first electronic component 150 is equal to the difference (absolute value) between the reference resistance value and the upper limit value of the resistance value of the second electronic component 250, and the difference (absolute value) between the reference resistance value and the upper limit value of the resistance value of the first electronic component 150 is equal to the difference (absolute value) between the reference resistance value and the lower limit value of the resistance value of the second electronic component 250. In other words, the first error range and the second error range are symmetrical to each other with respect to the reference characteristic value (reference resistance value in the present embodiment). In other words, the first error range and the second error range are equally offset from the reference characteristic value by the same amount (on a positive side and a negative side, respectively), and the lengths thereof (error widths) are the same.

The second electronic component package 210 is transferred from a manufacturing factory to a user's factory in a state of being wound in the second reel body 260 and stored as needed. In the present embodiment, the second reel body 260 is provided with a second indicator portion 270. The second indicator portion 270 indicates the reference resistance value (reference characteristic value) and the second characteristic value (second resistance value) of the second electronic component 250. The display mode of the second indicator portion 270 is not specifically limited. Examples thereof include “100 Ω−1˜−2Ω” and “reference resistance value 100Ω, resistance value error range −1˜−2%” when the reference resistance value is 100Ω, and the error range of the resistance value (second resistance value) is 1 to 2% of the reference resistance value on the negative side. The second indicator portion 270 is constituted by an indication label attached to an appropriate position of the second reel body 260, for example. The configuration of the second indicator portion is not limited thereto, and may be realized by performing printing at an appropriate position of the second electronic component package 210 (e.g., cover tape 230), or the portion may be provided on both of the second reel body 260 and the second electronic component package 210.

Next, advantages of the electronic component reel set A1 will be described.

The electronic component reel set A1 includes the first electronic component reel 10 and the second electronic component reel 20. The first electronic component reel 10 includes a plurality of first electronic components 150, and the second electronic component reel 20 includes a plurality of second electronic components 250. When a user uses the first electronic component 150 and the second electronic component 250, the first electronic component package 110 is fed from the first reel body 160, and a first electronic component 150 stored in the first electronic component package 110 is taken out, for example. Similarly, the second electronic component package 210 is fed from the second reel body 260, and a second electronic component 250 stored in the second electronic component package 210 is taken out. The first electronic component 150 and the second electronic component 250 that are taken out are mounted on a circuit board, for example.

The first electronic component 150 and the second electronic component 250 are connected in parallel on the circuit board. The resistance value of the first electronic component 150 is larger than the reference resistance value, and the resistance value of the second electronic component 250 is smaller than the reference resistance value. Accordingly, the error of the combined resistance of the first electronic component 150 having positive error and the second electronic component 250 having negative error with respect to the reference resistance value is lower than in the case where only the first electronic components 150 or the second electronic components 250 are used, and a normal product-level error can be achieved. In this way, as a result of using the first electronic component 150 and the second electronic component 250 that are supplied from the electronic component reel set A1 in a combined manner, the first electronic components 150 and the second electronic components 250 can be effectively used, and the product manufacturing yield can be improved.

The first electronic component reel 10 (first reel body 160) is provided with the first indicator portion 170, and the second electronic component reel 20 (second reel body 260) is provided with the second indicator portion 270. According to such a configuration, the first and second electronic components 150 and 250 that are respectively stored in the first and second electronic component reels 10 and 20 can be appropriately identified.

In some use examples, the absolute value of the difference between the reference resistance value and the first resistance value is the same as, or substantially the same as the absolute value of the difference between the reference resistance value and the second resistance value. According to such a configuration, it is possible to suppress the variation of the combined resistance when the first and second electronic components 150 and 250 are used in a combined manner.

For example, assume that the error of the resistance value of the first electronic component 150, relative to the reference resistance value Rref, is 1% on the positive side, and the error of the resistance value of the second electronic component 250 is 1% on the negative side. In this case, the combined resistance R0 of a resistance value R1 (1.01Rref) of the first electronic component 150 and a resistance value R2 (0.99Rref) of the second electronic component 250 can be calculated as R0=(R1×R2)/(R1+R2), and R0=(1.01Rref×0.99Rref)/(1.01Rref+0.99Rref)=0.49995Rref is obtained. Since the combined resistance of a parallel connection of resistors with no error (reference resistance value Rref) is 0.5Rref, the error of the combined resistance when the first electronic component 150 and the second electronic component 250 are connected in parallel is about 0.01% on the negative side. As a result of connecting the first electronic component 150 and the second electronic component 250 in parallel in this way, the error relative to the reference resistance value can be largely reduced.

When the first and second electronic components 150 and 250 are other electronic components (e.g., coils or capacitors) as well, the error relative to a reference characteristic value can be reduced by using the two components in a combined manner. When the first and second electronic components 150 and 250 are coils, the first electronic component 150 has a first inductance value serving as the first characteristic value, and the second electronic component 250 has a second inductance value serving as the second characteristic value. The first inductance value is larger than the reference inductance value, which is a reference characteristic value (i.e., includes positive error), and the second inductance value is smaller than the reference inductance value (i.e., includes negative error). As a result of connecting these first and second electronic components 150 and 250 in parallel, the error relative to the reference inductance value (reference characteristic value) can be effectively reduced.

When the first and second electronic components 150 and 250 are capacitors, the first electronic component 150 has a first static capacitance serving as the first characteristic value, and the second electronic component 250 has a second static capacitance serving as the second characteristic value. The first static capacitance is larger than a reference static capacitance, which is the reference characteristic value (i.e., includes positive error), and the second static capacitance is smaller than the reference static capacitance (i.e., includes negative error). As a result of connecting these first and second electronic components 150 and 250 in series, the error relative to the reference static capacitance (reference characteristic value) can be effectively reduced.

An electronic component module B1 according to a second embodiment will be described based on FIGS. 6 to 9. The illustrated electronic component module B1 includes a first electronic component 150, a second electronic component 250, a pair of terminal portions 310 and 320, and a sealing resin 400.

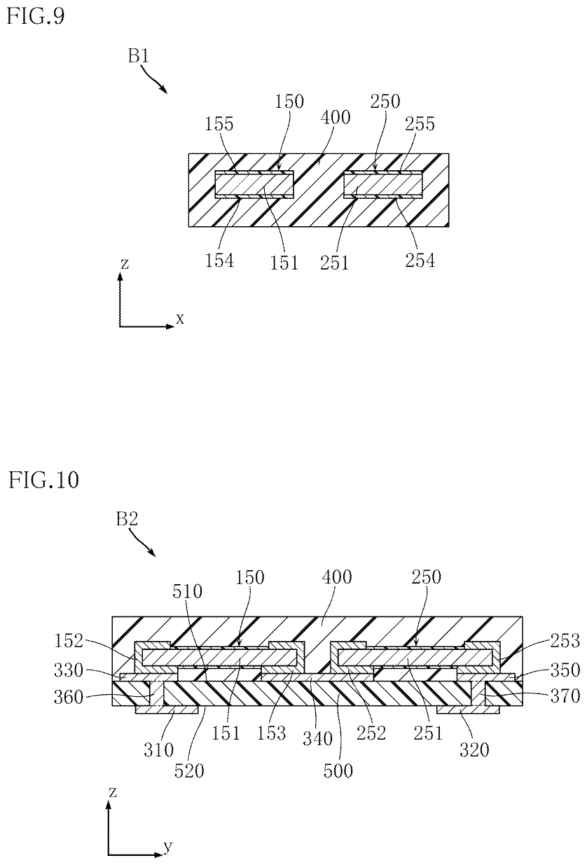

FIG. 6 is a perspective view illustrating the electronic component module B1. FIG. 7 is a plan view illustrating the electronic component module B1. FIG. 8 is a cross-sectional view taken along line VIII-VIII in FIG. 7. FIG. 9 is a cross-sectional view taken along line IX-IX in FIG. 7. In FIGS. 6 and 7, the sealing resin 400 is made transparent (refer to two-dot chain lines indicating the outer form of the sealing resin).

The electronic component module B1 is surface-mounted on a circuit board, for example. The electronic component module B1 has a rectangular chip shape in plan view. The thickness direction of the electronic component module B1 is denoted as a direction z. Also, two directions that are orthogonal to the direction z and are orthogonal to each other are denoted as a direction x and a direction y. The direction x is parallel with one side of the electronic component module B1 in plan view (viewed along the direction z), and the direction y is parallel with another side of the electronic component module B1.

The size of the electronic component module B1 is not specifically limited. For example, the size along the direction x is 0.8 to 10 mm, the size along the direction y is 0.8 to 10 mm, and the size along the direction z is 0.3 to 4 mm.

The terminal portions 310 and 320 are external connection terminals for mounting the electronic component module B1 on a circuit board or the like, and are made of a metal plate, for example. The material for constituting the metal plate is not specifically limited. Examples include Cu and a Cu alloy. The terminal portions 310 and 320 are apart from each other in the direction y, and are each shaped as an elongated rectangle that extends in the direction x.

First and second electronic components 150 and 250 in the electronic component module B1 of the present embodiment are configured similarly to the first and second electronic components 150 and 250 in the electronic component reel set A1 described above, and therefore the detailed description of the configuration will be omitted.

The first and second electronic components 150 and 250 are apart from each other in the direction x, and are arranged such that the longitudinal direction of the components extends along the direction y. One electrode 152 of the first electronic component 150 and one electrode 252 of the second electronic component 250 are joined to an upper face of the terminal portion 310 via a conductive joining material (not illustrated). The other electrode 153 of the first electronic component 150 and the other electrode 253 of the second electronic component 250 are joined to an upper face of the terminal portion 320 via a conductive joining material (not illustrated). As a result of such a configuration, the first and second electronic components 150 and 250 are connected, in parallel, to the terminal portions 310 and 320.

The sealing resin 400 covers the entirety of the first and second electronic components 150 and 250 and portions of the terminal portions 310 and 320, as shown in FIGS. 6 to 9. The material that constitutes the sealing resin 400 is a black epoxy resin, for example.

Some side faces of the terminal portion 310 and the lower face of the same are exposed from the sealing resin 400. Also some side faces of the terminal portion 320 are the lower face of the same are exposed from the sealing resin 400. These exposed portions of the terminal portions 310 and 320 are to be conductively joined to terminals of a circuit board via a joining material such as solder (not illustrated).

Next, effects of the electronic component module B1 will be described.

The electronic component module B1 include first and second electronic components 150 and 250. These first and second electronic components 150 and 250 are connected, in parallel, to the terminal portions 310 and 320, and are integrated with each other using the sealing resin 400. According to such a configuration, the first and second electronic components 150 and 250 can be effectively used as an electronic component module that has a more precise characteristic value. As can be understood from the description of the electronic component reel set A1 of the first embodiment, the first and second electronic components 150 and 250 that are connected, in parallel, to the terminal portions 310 and 320 are resistors or coils, for example.

The first and second electronic components 150 and 250 are incorporated in the electronic component module B1 in advance, and are electrically connected, in parallel, to the terminal portions 310 and 320. Accordingly, there is no concern of confusing the first electronic component 150 with the second electronic component 250. Therefore, the first and second electronic components 150 and 250 can be appropriately mounted on a circuit board or the like, in a state in which the components are combined.

An electronic component module B2 according to a third embodiment will be described based on FIG. 10. FIG. 10 is a cross-sectional view similar to FIG. 8. In the electronic component module B2, mainly the arrangement and connection of first and second electronic components 150 and 250 are different from the configuration of the electronic component module B1 described above.

The electronic component module B2 is additionally provided with internal terminals 330, 340, and 350, connection portions 360 and 370, and a support substrate 500. In FIG. 10, the same or similar constituent elements as those of the electronic component module B1 described above are assigned the same reference numerals, and redundant description thereof is omitted.

The support substrate 500 supports the first and second electronic components 150 and 250 via the internal terminals 330, 340, and 350. The support substrate 500 is made of an insulating material. The material of the support substrate 500 is not specifically limited. Examples thereof include an epoxy resin, a glass epoxy resin, and ceramics. The support substrate 500 has a support face 510 and a bottom face 520. The support face 510 is a flat face facing in the direction z. The bottom face 520 is a flat face on the side opposite to the support face 510.

The internal terminals 330, 340, and 350 are provided on the support face 510 of the support substrate 500, and are parts that form conduction paths to the first and second electronic components 150 and 250. The material of the internal terminals 330, 340, and 350 is not specifically limited. Examples thereof include a metal such as Cu, Ni, Ti, or Au. Also, the method of forming the internal terminals 330, 340, and 350 is not specifically limited. In the illustrated example, they are formed by plating, for example.

The internal terminals 330, 340, and 350 are provided apart from each other in the direction y. One electrode 152 of the first electronic component 150 is conductively joined to the internal terminal 330 via a joining material (not illustrated). The other electrode 153 of the first electronic component 150 and one electrode 252 of the second electronic component 250 are conductively joined to the internal terminal 340 via a joining material (not illustrated). The other electrode 253 of the second electronic component 250 is conductively joined to the internal terminal 350 via a joining material (not illustrated).

The terminal portions 310 and 320 are provided on the bottom face 520 of the support substrate 500. The material of the terminal portions 310 and 320 is not specifically limited. Examples thereof include a metal such as Cu, Ni, Ti, or Au. The method of forming the terminal portions 310 and 320 is not specifically limited. In the illustrated example, they are formed by plating, for example.

The connection portion 360 electrically connects the internal terminal 330 and the terminal portion 310. The connection portion 370 electrically connects the internal terminal 350 and the terminal portion 320. The specific configuration of the connection portions 360 and 370 is not specifically limited, and in the present embodiment, the connection portions 360 and 370 pass through the support substrate 500 in the thickness direction, in an inner region of the support substrate 500 viewed along the direction z. Such connection portions 360 and 370 are provided by filling through holes formed in the support substrate 500 with metal, and reach the support face 510 and the bottom face 520. As an alternative to the illustrated example, the connection portions 360 and 370 may also be provided by forming plating layers made of metal on internal faces of through holes formed in the support substrate 500, and in this case, the connection portions 360 and 370 are filled with resin.

The sealing resin 400 is arranged on the support face 510 of the support substrate 500, and covers the support face 510 and the first and second electronic components 150 and 250.

According to the configuration described above, in the electronic component module B2, the first and second electronic components 150 and 250 are connected, in series, to the terminal portions 310 and 320.

The electronic component module B2 includes first and second electronic components 150 and 250. These first and second electronic components 150 and 250 are connected, in series, to the terminal portions 310 and 320, and are integrated with each other by the sealing resin 400. According to such a configuration, the first and second electronic components 150 and 250 can be effectively used as an electronic component module that has a more precise characteristic value. As can be understood from the description of the electronic component reel set A1 of the first embodiment, the first and second electronic components 150 and 250 that are connected, in series, to the terminal portions 310 and 320 are capacitors, for example.

The first and second electronic components 150 and 250 are incorporated in the electronic component module B2 in advance, and are electrically connected, in series, to the terminal portions 310 and 320. Accordingly, there is no concern of confusing the first electronic component 150 with the second electronic component 250. Therefore, the first and second electronic components 150 and 250 can be appropriately mounted on a circuit board or the like, in a state in which the components are combined.

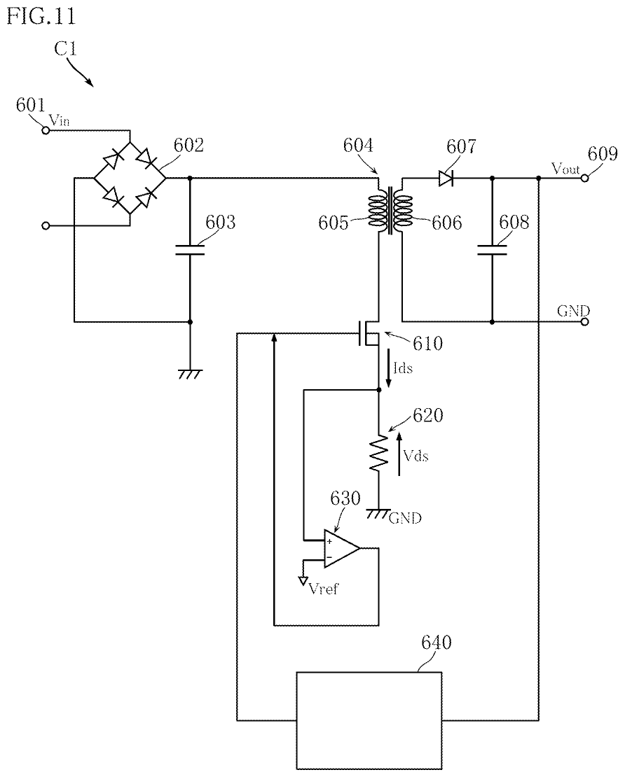

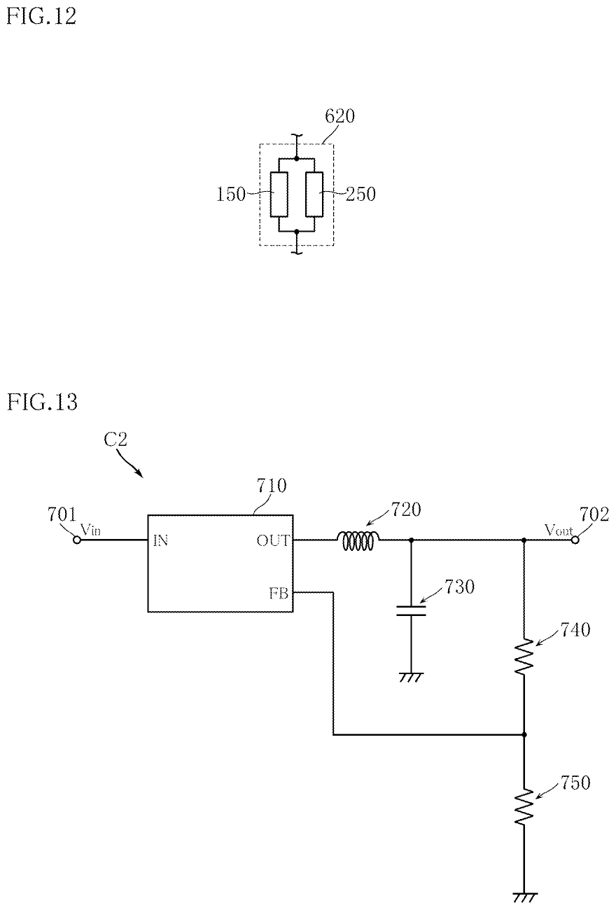

An electric circuit C1 according to a fourth embodiment will be described based on FIGS. 11 and 12. FIG. 11 is a block diagram illustrating a schematic configuration of the electric circuit C1 in which first and second electronic components 150 and 250, which are resistors, are used in a combined manner. FIG. 11 shows an example in which the electric circuit C1 includes an input terminal 601, a rectifying unit 602, a transforming unit 604, an output terminal 609, a switch element 610, a current detection resistor 620, a comparator 630, and a control unit 640, and is applied to an AC/DC converter.

The input terminal 601 is for receiving an AC voltage from a power supply unit (not illustrated). The rectifying unit 602 is a diode bridge rectifier for full-wave-rectifying the AC voltage, and is connected to the input terminal 601. The output voltage of the rectifying unit 602 is smoothed by the capacitor 603, and thus the AC voltage is converted to a DC voltage. The transforming unit 604 is a transformer that includes a primary coil 605 and a secondary coil 606.

The switch element (functional unit) 610 is connected to the primary coil 605 of the transforming unit 604. The switch element 610 is a field effect transistor (N-channel MOSFET), for example.

The output terminal 609 is connected to the secondary coil 606 of the transforming unit 604. The control unit 640 drives the switch element 610 by switching the element on and off. As a result of switching the switch element 610 on and off, the DC voltage on the primary coil 605 side is stepped down, and an output voltage stabilized to a target value is supplied to a load (not illustrated) connected to the output terminal 609. A rectifier diode 607 and an output capacitor 608 are provided on the output side of the transforming unit 604.

The current detection resistor (resistor portion) 620 is connected to the switch element 610, and is connected between the switch element 610 and ground. When the switch element 610 is in an on state, a current Ids that flows through the primary coil 605 of the transforming unit 604 flows through the current detection resistor 620. Therefore, a detecting voltage Vds that is proportional to the current Ids is generated in the current detection resistor 620. The resistance value of the current detection resistor 620 is several tens of mΩ to several hundreds of Ω, for example. Therefore, even if the current Ids flowing through the current detection resistor 620 is in the range of several A to around a dozen A, the detecting voltage Vds can be kept low.

The comparator 630 compares the voltage (detecting voltage Vds) of the current detection resistor 620 with a reference voltage Vref, and outputs a comparison result. If the detecting voltage Vds is larger than the reference voltage Vref, the switch element 610 is turned off by an output signal from the comparator 630. In this way, the current detection resistor 620 has a function of preventing overcurrent from flowing in the primary coil 605. The current detection resistor 620 and the comparator 630 are functional units that act on the switch element 610.

As shown in FIG. 12, the current detection resistor 620 includes first and second electronic components 150 and 250 (chip resistors) that are similar to the components described above. The first electronic component 150 has a resistance value (first resistance value) larger than a reference resistance value. The second electronic component 250 has a resistance value (second resistance value) smaller than the reference resistance value. These first and second electronic components 150 and 250 are connected in parallel.

The current detection resistor 620 is formed by connecting the first and second electronic components 150 and 250 in parallel. Accordingly, the resistance value of the current detection resistor 620 (combined resistance of the first and second electronic components 150 and 250) is close to a reference resistance value, and a highly accurate resistor can be realized. Therefore, the electric circuit C1 including the current detection resistor 620 can supply an output voltage that is stabilized to a value close to a target value.

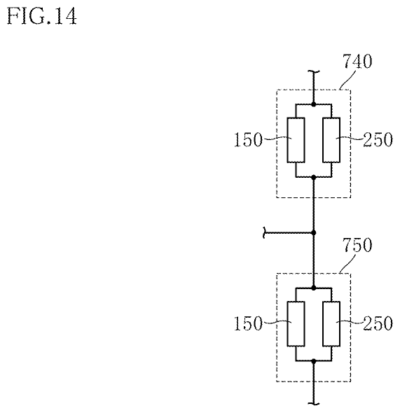

An electric circuit C2 according to a fifth embodiment will be described based on FIGS. 13 and 14. FIG. 13 is a block diagram illustrating a schematic configuration of the electric circuit C2 in which first and second electronic components 150 and 250, which are resistors, are used in combination. FIG. 13 shows an example in which the electric circuit C2 includes an input terminal 701, a control unit 710, an output terminal 702, a coil 720, a capacitor 730, a first voltage-dividing resistor 740, and a second voltage-dividing resistor 750, and is applied to a DC/DC converter.

The input terminal 701 is for receiving a DC voltage. The control unit (functional unit) 710 is connected to the input terminal 701, steps down the DC voltage from the input terminal 701, and supplies an output voltage that is stabilized to a target value to the output terminal 702. The coil 720 and the capacitor 730 constitute a low pass filter, and the output voltage from the control unit 710 is averaged by the coil 720 and the capacitor 730.

The output voltage from the control unit 710 is divided by first and second voltage-dividing resistors 740 and 750. The divided voltage is fed back to the control unit 710, and the duty ratio of a switching driving pulse is adjusted such that this voltage matches an internal reference voltage. As a result, the output voltage is stabilized to a target voltage.

As shown in FIG. 14, the first and second voltage-dividing resistors 740 and 750 each include first and second electronic components 150 and 250 (chip resistors) that are similar to the components described above. Each first electronic component 150 has a resistance value (first resistance value) larger than a reference resistance value. Each second electronic component 250 has a resistance value (second resistance value) smaller than the reference resistance value. In each of the first and second voltage-dividing resistors 740 and 750, the first and second electronic components 150 and 250 are connected in parallel.

In the present embodiment, the first and second voltage-dividing resistors 740 and 750 are each formed by connecting the first and second electronic components 150 and 250 in parallel. Accordingly, the resistance values of the first and second voltage-dividing resistors 740 and 750 (combined resistance of the first and second electronic components 150 and 250) are each close to a reference resistance value, and highly accurate resistors can be realized. Therefore, the electric circuit C2 including the first and second voltage-dividing resistors 740 and 750 (first and second electronic components 150 and 250 connected in parallel) can supply an output voltage that is stabilized to a value close to a target value.

Embodiments of the present disclosure have been described, but the present disclosure is not limited thereto, and can be modified in various ways without departing from the concept of the invention.

The present disclosure includes the configurations described in the following clauses.

Clause 1.

An electronic component reel set comprising:

a first electronic component reel; and

a second electronic component reel,

wherein the first electronic component reel includes: a plurality of first electronic components each having a first characteristic value falling in a predetermined range above a reference characteristic value; a first electronic component package that stores the plurality of first electronic components linearly; a first reel body in which the first electronic component package is wound; and a first indicator portion that indicates the first characteristic value, and

the second electronic component reel includes: a plurality of second electronic components each having a second characteristic value in a predetermined range below the reference characteristic value; a second electronic component package that stores the plurality of second electronic components linearly; a second reel body in which the second electronic component package is wound; and a second indicator portion that indicates the second characteristic value.

Clause 2.

The electronic component reel according to Clause 1, wherein the first indicator portion and the second indicator portion indicate the reference characteristic value.

Clause 3.

The electronic component reel according to Clause 1 or 2, wherein the first electronic components and the second electronic components are resistors, and the reference characteristic value is a reference resistance value,

the first electronic components have a first resistance value as the first characteristic value, the first resistance value being larger than the reference resistance value, and

the second electronic component has a second resistance value as the second characteristic value, the second resistance value being smaller than the reference resistance value.

Clause 4.

The electronic component reel according to Clause 1 or 2, wherein the first electronic components and the second electronic components are coils, and the reference characteristic value is a reference inductance value,

the first electronic components have a first inductance value as the first characteristic value, the first inductance value being larger than the reference inductance value, and

the second electronic component has a second inductance value as the second characteristic value, the second inductance value being smaller than the reference inductance value.

Clause 5.

The electronic component reel according to Clause 1 or 2, wherein the first electronic components and the second electronic components are capacitors, and the reference characteristic value is a reference static capacitance,

the first electronic components have a first static capacitance as the first characteristic value, the first static capacitance being larger than the reference static capacitance, and

the second electronic components have a second static capacitance as the second characteristic value, the second static capacitance being smaller than the reference static capacitance.

Clause 6.

The electronic component reel according to any one of Clauses 1 to 5, wherein a first error range corresponding to a difference between the reference characteristic value and the first characteristic value is equivalent to a second error range corresponding to a difference between the reference characteristic value and the second characteristic value.

Clause 7.

An electronic component module comprising:

a first electronic component having a first characteristic value falling in a predetermined range that is above a reference characteristic value;

a second electronic component having a second characteristic value falling in a predetermined range that is below smaller than the reference characteristic value;

a terminal portion configured for external connection and electrically connected to the first electronic component and the second electronic component; and

a sealing resin that covers the first electronic component and the second electronic component.

Clause 8.

The electronic component module according to Clause 7, wherein the first electronic component and the second electronic component are connected in parallel to the terminal portion.

Clause 9.

The electronic component module according to Clause 7 or 8, wherein the first electronic component and the second electronic component are resistors.

Clause 10.

The electronic component module according to Clause 7 or 8, wherein the first electronic component and the second electronic component are coils.

Clause 11.

The electronic component module according to Clause 7, wherein the first electronic component and the second electronic component are connected in series to the terminal portion.

Clause 12.

The electronic component module according to Clause 11, wherein the first electronic component and the second electronic component are capacitors.

Clause 13.

An electric circuit comprising:

a functional unit having a predetermined function; and

at least one resistor portion connected to the functional unit,

wherein the resistor portion includes a first resistor having a first resistance value falling in a predetermined range above a reference resistance value, and a second resistor having a second resistance value falling in a predetermined range below the reference resistance value, and

the first and second resistors are connected in parallel.

Clause 14.

The electric circuit according to Clause 13, further comprising:

an input terminal configured to receive an AC voltage;

a rectifying unit connected to the input terminal;

a transforming unit that includes a primary coil and a secondary coil, the primary coil being connected to the rectifying unit;

an output terminal connected to the secondary coil; and

a control unit,

wherein the functional unit comprises a switch element connected to the primary coil, and the control unit is configured to drive the switch element.

Clause 15.

The electric circuit according to Clause 13, further comprising:

an input terminal configured to receive a DC voltage; and

an output terminal,

wherein the functional unit comprises a control unit connected to the input terminal, and an output voltage from the control unit is supplied to the output terminal, and

the resistor portion includes a first voltage-dividing resistor and a second voltage-dividing resistor, thereby dividing the output voltage from the control unit.

### REFERENCE NUMERALS

A1 Electronic component reel
B1, B2 Electronic component module
C1, C2 Electric circuit
10 First electronic component reel
110 First electronic component package
120 Carrier tape
121 Principal face
122 Storage recess
130 Cover tape
140 Joining portion
150 First electronic component
151 Base material
152, 153 Electrode
154, 155 Insulating film
160 First reel body
170 First indicator portion
20 Second electronic component reel
210 Second electronic component package
220 Carrier tape
221 Principal face
222 Storage recess
230 Cover tape
240 Joining portion
250 Second electronic component
251 Base material
252, 253 Electrode
254, 255 Insulating film
260 Second reel body
270 Second indicator portion
310, 320 Terminal portion
330, 340, 350 Internal terminal
360, 370 Connection portion
400 Sealing resin
500 Support substrate
510 Support face
520 Bottom face
601 Input terminal
602 Rectifying unit
603 Capacitor
604 Transforming unit
605 Primary coil
606 Secondary coil
607 Rectifier diode
608 Capacitor
609 Output terminal
610 Switch element
620 Current detection resistor
630 Comparator
640 Control unit
701 Input terminal
702 Output terminal
710 Control unit
720 Coil
730 Capacitor
740 First voltage-dividing resistor
750 Second voltage-dividing resistor
x Direction
y Direction
z Direction

1. An electronic component reel set comprising:
a first electronic component reel; and
a second electronic component reel,
wherein the first electronic component reel includes: a plurality of first electronic components each having a first characteristic value falling in a predetermined range above a reference characteristic value; a first electronic component package that stores the plurality of first electronic components linearly; a first reel body in which the first electronic component package is wound; and a first indicator portion that indicates the first characteristic value, and
the second electronic component reel includes: a plurality of second electronic components each having a second characteristic value in a predetermined range below the reference characteristic value; a second electronic component package that stores the plurality of second electronic components linearly; a second reel body in which the second electronic component package is wound; and a second indicator portion that indicates the second characteristic value.

2. The electronic component reel according to claim 1, wherein the first indicator portion and the second indicator portion indicate the reference characteristic value.

3. The electronic component reel according to claim 1, wherein the first electronic components and the second electronic components are resistors, and the reference characteristic value is a reference resistance value,
the first electronic components have a first resistance value as the first characteristic value, the first resistance value being larger than the reference resistance value, and
the second electronic component has a second resistance value as the second characteristic value, the second resistance value being smaller than the reference resistance value.

4. The electronic component reel according to claim 1, wherein the first electronic components and the second electronic components are coils, and the reference characteristic value is a reference inductance value,
the first electronic components have a first inductance value as the first characteristic value, the first inductance value being larger than the reference inductance value, and
the second electronic component has a second inductance value as the second characteristic value, the second inductance value being smaller than the reference inductance value.

5. The electronic component reel according to claim 1, wherein the first electronic components and the second electronic components are capacitors, and the reference characteristic value is a reference static capacitance,
the first electronic components have a first static capacitance as the first characteristic value, the first static capacitance being larger than the reference static capacitance, and
the second electronic components have a second static capacitance as the second characteristic value, the second static capacitance being smaller than the reference static capacitance.

6. The electronic component reel according to claim 1, wherein a first error range corresponding to a difference between the reference characteristic value and the first characteristic value is equivalent to a second error range corresponding to a difference between the reference characteristic value and the second characteristic value.

7. An electronic component module comprising:
a first electronic component having a first characteristic value falling in a predetermined range that is above a reference characteristic value;
a second electronic component having a second characteristic value falling in a predetermined range that is below smaller than the reference characteristic value;
a terminal portion configured for external connection and electrically connected to the first electronic component and the second electronic component; and
a sealing resin that covers the first electronic component and the second electronic component.

8. The electronic component module according to claim 7, wherein the first electronic component and the second electronic component are connected in parallel to the terminal portion.

9. The electronic component module according to claim 7, wherein the first electronic component and the second electronic component are resistors.

10. The electronic component module according to claim 7, wherein the first electronic component and the second electronic component are coils.

11. The electronic component module according to claim 7, wherein the first electronic component and the second electronic component are connected in series to the terminal portion.

12. The electronic component module according to claim 11, wherein the first electronic component and the second electronic component are capacitors.

13. An electric circuit comprising:
a functional unit having a predetermined function; and
at least one resistor portion connected to the functional unit,
wherein the resistor portion includes a first resistor having a first resistance value falling in a predetermined range above a reference resistance value, and a second resistor having a second resistance value falling in a predetermined range below the reference resistance value, and
the first and second resistors are connected in parallel.

14. The electric circuit according to claim 13, further comprising:
an input terminal configured to receive an AC voltage;
a rectifying unit connected to the input terminal;
a transforming unit that includes a primary coil and a secondary coil, the primary coil being connected to the rectifying unit;
an output terminal connected to the secondary coil; and
a control unit,
wherein the functional unit comprises a switch element connected to the primary coil, and the control unit is configured to drive the switch element.

15. The electric circuit according to claim 13, further comprising:
an input terminal configured to receive a DC voltage; and
an output terminal,
wherein the functional unit comprises a control unit connected to the input terminal, and an output voltage from the control unit is supplied to the output terminal, and
the resistor portion includes a first voltage-dividing resistor and a second voltage-dividing resistor, thereby dividing the output voltage from the control unit.
